(19) United States
(12) Patent Application Publication
(10) Pub. No.: US 2026/0223347 A1
(43) Pub. Date: Jul. 30, 2026

(54) PRODUCTION GUIDANCE DEVICE AND PRODUCTION GUIDANCE METHOD

(71) Applicant: FUJI CORPORATION, Chiryu (JP)

(72) Inventors: Mitsuru SANJI, Toyota-shi (JP); Kenji HARA, Kariya-shi (JP)

(73) Assignee: FUJI CORPORATION, Chiryu (JP)

(21) Appl. No.: 19/146,010

(22) PCT Filed: Feb. 1, 2023
(86) PCT No.: PCT/JP2023/003232

§ 371 Date: Jul. 7, 2025

(51) Int. Cl. H05K 13/08; H05K 13/04

(52) U.S. Cl. CPC H05K 13/086; H05K 13/0417

(57) ABSTRACT

A production guidance device includes a plan section and a guidance section. The plan section is configured to plan a timing for pre-supplying a device, which is necessary for changeover work of a board work machine and replenishment work of the device with respect to the board work machine, from a storage device to an empty region of at least one of a first slot and a second slot by using a conveyance device. The guidance section is configured to provide a worker with a guidance of supply of the device to the storage device during a predetermined period before the timing for pre-supply planned by the plan section.

### TECHNICAL FIELD

The present description discloses a technique related to a production guidance device and a production guidance method.

### BACKGROUND ART

A production system described in Patent Literature 1 includes a production plan detailing section and a setup support section. After component shortage prediction processing is executed, the production plan detailing section executes preliminary preparation list printing such as a work instruction slip (for example, a necessary component list, a replenishment component list, and a stockout list for handling a component re-delivery) when the production plan is executed. The setup support section issues an operation instruction during model switching (for example, whether to return a reel member or divert the reel member). As described above, the production system described in Patent Literature 1 performs planning of changeover work and planning of component replenishment work, and provides a guidance of the changeover work and a guidance of the component replenishment work.

### CITATION LIST

### Patent Literature

Patent Literature 1: JP-A-H11-232339

### BRIEF SUMMARY

### Technical Problem

However, in the production system described in Patent Literature 1, it is necessary for a worker to prepare each of the devices necessary for the changeover work of the board work machine and the devices necessary for the replenishment work of the board work machine, and to supply the devices to the board work machine. Therefore, the work of the worker becomes complicated, and the work efficiency may decrease.

In view of such circumstances, the present description discloses a production guidance device and a production guidance method capable of improving work efficiency of changeover work and replenishment work of a board work machine.

### Solution to Problem

The present description discloses a production guidance device to be applied to a production line. The production line includes a board work machine, a storage device, and a conveyance device. The board work machine includes a first slot capable of holding a device to be used for production of a product board and a second slot capable of preliminarily holding the device that is scheduled to be used in the production of the product board or capable of temporarily holding the device that is no longer necessary for the production of the product board, and is configured to perform predetermined board work on a board to produce the product board. The storage device is capable of preliminarily holding the device that is scheduled to be used in the production of the product board or capable of temporarily holding the device that is no longer necessary for the production of the product board. The conveyance device is configured to supply the device supplied to the storage device to the first slot or the second slot and collect the device that is no longer necessary for the production of the product board from the first slot or the second slot to the storage device. The production guidance device includes a plan section and a guidance section. The plan section is configured to plan a timing for pre-supplying the device, which is necessary for changeover work of the board work machine and replenishment work of the device with respect to the board work machine, from the storage device to an empty region of at least one of the first slot and the second slot by using the conveyance device. The guidance section is configured to provide a worker with a guidance of supply of the device to the storage device during a predetermined period before the timing for pre-supplying planned by the plan section.

The present description also discloses a production guidance method to be applied to a production line. The production line includes a board work machine, a storage device, and a conveyance device. The board work machine includes a first slot capable of holding a device to be used for production of a product board and a second slot capable of preliminarily holding the device that is scheduled to be used in the production of the product board or capable of temporarily holding the device that is no longer necessary for the production of the product board, and is configured to perform predetermined board work on a board to produce the product board. The storage device is capable of preliminarily holding the device that is scheduled to be used in the production of the product board or capable of temporarily holding the device that is no longer necessary for the production of the product board. The conveyance device is configured to supply the device supplied to the storage device to the first slot or the second slot and collect the device that is no longer necessary for the production of the product board from the first slot or the second slot to the storage device. The production guidance method includes a plan step and a guidance step. In the plan step, a timing for pre-supplying the device, which is necessary for changeover work of the board work machine and replenishment work of the device with respect to the board work machine, from the storage device to an empty region of at least one of the first slot and the second slot by using the conveyance device is planned. In the guidance step, a worker is provided with a guidance of supply of the device to the storage device during a predetermined period before the timing for pre-supplying planned by the plan step.

### Advantageous Effects

In the above-described production line, it is possible to pre-supply the device necessary for the changeover work of the board work machine and the replenishment work of the device with respect to the board work machine. In addition, with the production guidance device described above, it is possible to provide the worker with the guidance of the supply of the device during the predetermined period before the timing for pre-supplying the device. Therefore, the worker can collectively perform the preparation work of the devices without distinguishing the changeover work and the replenishment work of the board work machine, and the work efficiency of the worker is improved. The above description regarding the production guidance device can be similarly applied to the production guidance method.

### BRIEF DESCRIPTION OF DRAWINGS

FIG. 1 is a plan view illustrating a configuration example of a board production line.

FIG. 2 is a perspective view illustrating a configuration example of an exchange system and a component mounter illustrated in FIG. 1.

FIG. 3 is a plan view illustrating an example of an exchange operation of a feeder between a conveyance device and a component supply device of the component mounter.

FIG. 4 is a block diagram illustrating an example of control blocks of a production guidance device.

FIG. 5 is a flowchart illustrating an example of a control procedure performed by the production guidance device.

FIG. 6 is a schematic diagram illustrating an example of a temporal change in a remaining number of articles.

FIG. 7 is a schematic diagram illustrating an example of a guidance for providing a guidance of supply of a device to the storage device.

### DESCRIPTION OF EMBODIMENTS

### 1. Embodiment

### 1-1. Configuration Example of Production Line WL0

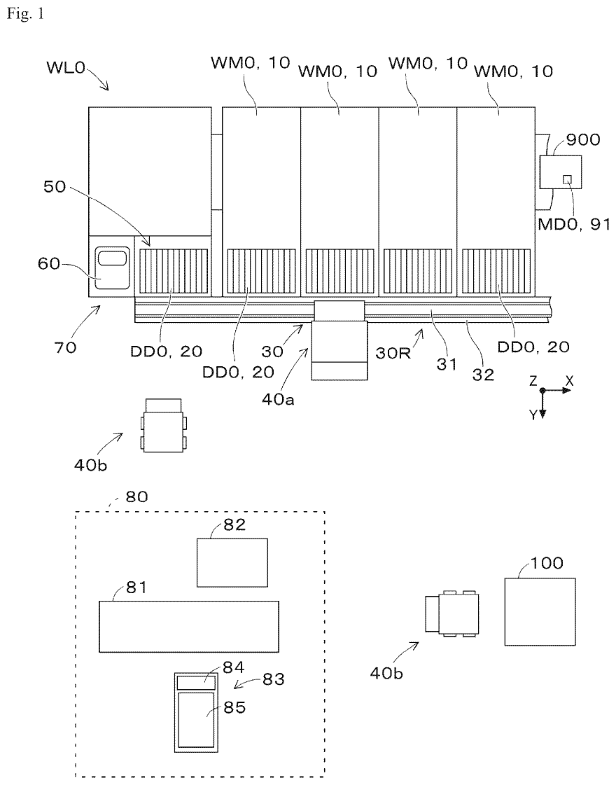

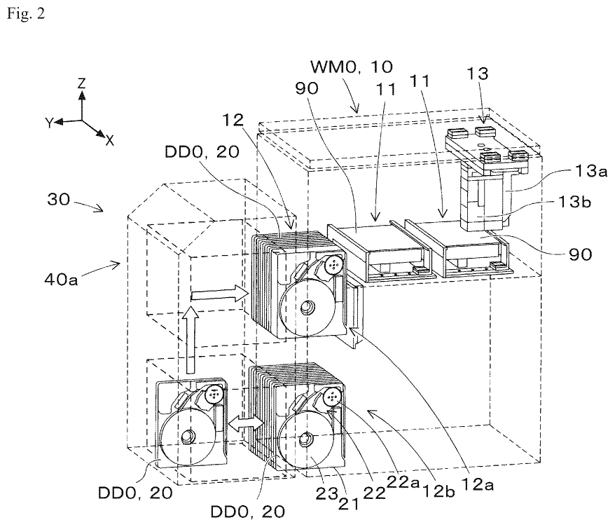

Production guidance device 70 of the embodiment is applied to production line WL0. As illustrated in FIG. 1, production line WL0 includes at least one component mounter 10 (four in the same drawing), exchange system 30, conveyance device 40a, storage device 50, and line management device 60. Four component mounters 10 are installed along a conveyance direction (X direction) of board 90 illustrated in FIG. 2. Component mounter 10 is included in board work machine WM0 that performs predetermined board work on board 90. The board work performed by component mounter 10 includes carrying-in work and carrying-out work of board 90, and supply work, pick-up work, mounting work, and the like of component 91. Cassette-type feeder 20 is, for example, detachably provided in component mounter 10.

Storage device 50 used for storing feeder 20 is installed, for example, on a board carrying-in side of production line WL0 (on a left side in the drawing in FIG. 1). In addition, exchange system 30 and conveyance device 40a are provided in production line WL0, and perform supply work, an exchange operation, and collection work of feeder 20. The configuration of production line WL0 may be added as appropriate or changed in accordance with, for example, a type of product board 900 to be produced. Specifically, board work machine WM0 such as a solder printer, a solder inspector, a reflow oven, and a visual inspector can be installed as appropriate in production line WL0. As described above, production line WL0 can subsequently convey board 90 by using various board work machines WM0, execute a production process including an inspection process, and produce product board 900.

Board work machine WM0 constituting production line WL0 is configured to input and output various data to and from line management device 60 via a network. For example, storage device 50 includes multiple slots. Storage device 50 stocks feeders 20 installed in the multiple slots. Feeder 20 installed in the slot of storage device 50 is in a state of being capable of communicating with line management device 60. As a result, the slot of storage device 50 and identification information of feeder 20 installed in the slot are recorded in line management device 60 in association with each other.

In addition, line management device 60 monitors an operation status of production line WL0, and integrally controls board work machine WM0 such as component mounter 10, exchange system 30, conveyance device 40a, and storage device 50. Line management device 60 stores various data for controlling board work machine WM0, exchange system 30, conveyance device 40a, and storage device 50. Line management device 60 transmits various data such as a production program when, for example, component mounter 10 executes a mounting process of component 91.

### 1-2. Configuration Example of Component Mounter 10

As illustrated in FIG. 2, each of four component mounters 10 includes board conveyance device 11, component supply device 12, and head drive device 13. In the present description, the conveyance direction of board 90 is defined as the X direction. In addition, a direction orthogonal to the X direction in a horizontal plane is defined as a Y direction. Further, a vertical direction (up-down direction in the drawing in FIG. 2) orthogonal to the X direction and the Y direction is defined as a Z direction.

Board conveyance device 11 is configured with, for example, a belt conveyor and a positioning device. Board conveyance device 11 subsequently conveys board 90 in the conveyance direction (X direction) and positions board 90 at a predetermined position in the machine. Board conveyance device 11 carries board 90 out of component mounter 10 after the mounting process performed by component mounter 10 is completed.

Component supply device 12 supplies component 91 to be mounted on board 90. Component supply device 12 includes first slot 12a and second slot 12b that can be installed with multiple feeders 20. In the embodiment, first slot 12a is disposed in an upper portion of a front portion side of component mounter 10 to operably hold installed feeder 20. The operation of feeder 20 installed in first slot 12a is controlled in the mounting process performed by component mounter 10, and component 91 is supplied at a takeout section provided at a defined position at the upper portion of feeder 20. As described above, first slot 12a can hold feeder 20 used in the production of product board 900.

In the embodiment, second slot 12b is disposed below first slot 12a and stocks installed feeder 20. Specifically, second slot 12b preliminarily holds feeder 20 that is scheduled to be used in the production of product board 900. In addition, second slot 12b temporarily holds feeder 20 that is no longer necessary for the production of product board 900. The exchange operation of feeder 20 between first slot 12a and second slot 12b is performed by conveyance device 40a.

As illustrated in FIG. 2, feeder 20 includes feeder main body 21 and drive device 22. Feeder main body 21 of the embodiment is formed in a flat box shape. Feeder main body 21 detachably (exchangeably) holds reel 23 on which a carrier tape accommodating multiple components 91 is wound. Drive device 22 includes sprocket 22a that engages with a feeding hole provided in the carrier tape. Drive device 22 rotates sprocket 22a to feed and move the carrier tape.

The operation of drive device 22 of feeder 20 is controlled by a control device of component mounter 10. When feeder 20 is installed in first slot 12a of component mounter 10, feeder 20 receives power supplied from component mounter 10 via a connector, and is in a state of being capable of communicating with component mounter 10. As a result, component mounter 10 can detect the supply and the collection of feeder 20 in first slot 12a. The above description regarding first slot 12a can be similarly applied to second slot 12b.

The feeding operation of the carrier tape accommodating component 91, which is performed by feeder 20 installed in first slot 12a, is controlled based on a control instruction or the like by component mounter 10. As a result, feeder 20 supplies components 91 to be picked up by a holding member of mounting head 13b at the takeout section provided at the upper portion of feeder 20.

Head drive device 13 moves moving body 13a in the horizontal direction (X direction and Y direction) by a linear motion mechanism. Mounting head 13b is fixed to moving body 13a by a clamp member to be exchangeable (detachable). Mounting head 13b is moved in the X direction and the Y direction integrally with moving body 13a by the linear motion mechanism of head drive device 13. Mounting head 13b uses the holding member to pick up component 91 supplied by component supply device 12. As the holding member, for example, a suction nozzle that picks up component 91 by supplied negative pressure air, a chuck that grips component 91, or the like can be used.

Mounting head 13b holds the holding member to be movable in the Z direction and to be rotatable about a Q axis parallel to the Z direction. Mounting head 13b adjusts a position and an angle of the holding member in accordance with a posture of picked-up component 91. Mounting head 13b mounts component 91 at the mounting position on board 90 instructed by the production program. A total time of a time required for a predetermined number of cycles of a pick-and-place cycle of components 91 and a time required for carrying in and carrying out board 90 corresponds to a cycle time per board 90.

The holding member provided in mounting head 13b may be changed as appropriate in accordance with the type of component 91 in the mounting process of mounting component 91 on board 90. Component mounter 10 attaches the suction nozzle accommodated in a nozzle station to mounting head 13b, for example, when the suction nozzle used in the mounting process to be executed is not attached to mounting head 13b. The nozzle station is detachably installed at a predetermined position in component mounter 10 or on feeder 20.

### 1-3. Configuration Example of Exchange System 30 and Conveyance Device 40a

As illustrated in FIGS. 1 and 2, exchange system 30 includes first rail 31 and second rail 32. First rail 31 and second rail 32 form traveling path 30R of conveyance device 40a. First rail 31 extends in the conveyance direction (X direction) of board 90, and is provided between first slot 12a and second slot 12b in the vertical direction (Z direction).

Second rail 32 extends in the conveyance direction (X direction) of board 90, and is provided below second slot 12b in the vertical direction (Z direction). First rail 31 and second rail 32 extend over substantially the entire region of the conveyance direction (X direction) of board 90 in production line WL0. The conveyance direction (X direction) of board 90 corresponds to a disposition direction of four component mounters 10.

Conveyance device 40a is provided to be able to travel on traveling path 30R formed by first rail 31 and second rail 32. Conveyance device 40a receives power supplied from a power feeding section by non-contact power supply, for example, via a power receiving section provided to face the power feeding section provided on first rail 31. The power received by the power receiving section is used for traveling of conveyance device 40a, predetermined work, and the like via the power receiving circuit. Conveyance device 40a detects, for example, a position (current position) on traveling path 30R by using a position detection device. The position detection device can detect the position by using, for example, an optical detection method, a detection method using electromagnetic induction, or the like.

The predetermined work includes an exchange operation of exchanging device DD0 used in the production of product board 900 by board work machine WM0 such as component mounter 10, with board work machine WM0. Conveyance device 40a of the embodiment uses feeder 20 that supplies component 91 to be mounted on board 90 as device DD0, and performs the exchange operation of feeder 20 with component mounter 10 that is board work machine WM0. In addition, conveyance device 40a can perform the exchange operation of feeder 20 with storage device 50 using feeder 20 as device DD0.

Conveyance device 40a of the embodiment conveys feeder 20 from storage device 50 to first slot 12a or second slot 12b of component mounter 10, and performs the supply work of feeder 20. In addition, conveyance device 40a performs the exchange operation of feeder 20 between first slot 12a and second slot 12b of component mounter 10. Further, conveyance device 40a conveys feeder 20 that is no longer necessary, from component mounter 10 to storage device 50, and performs the collection work of feeder 20.

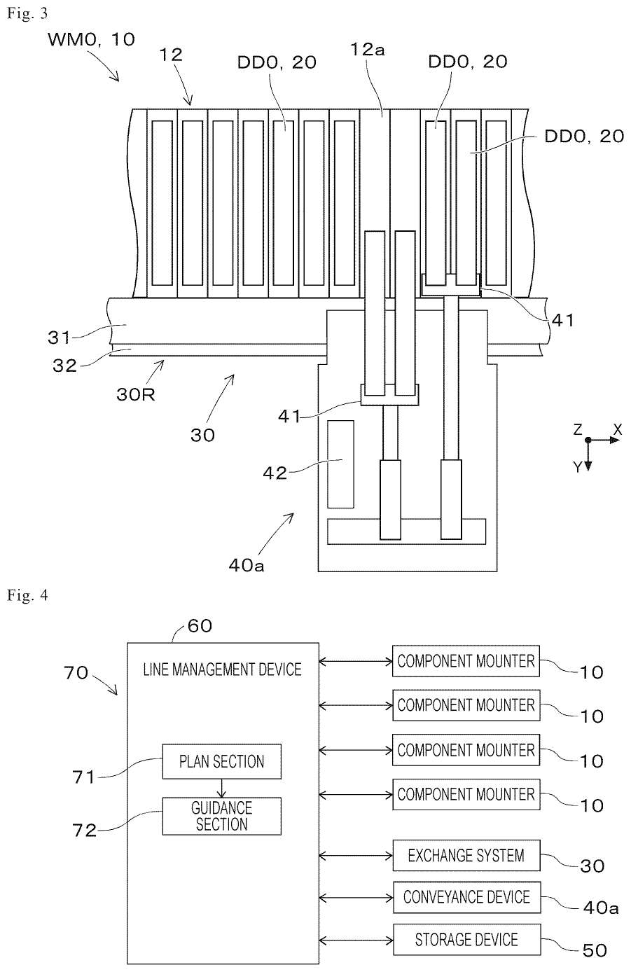

As illustrated in FIG. 3, conveyance device 40a includes at least one holding section 41 (two in the same drawing) and control device 42. In the embodiment, each of two holding sections 41 can simultaneously clamp multiple (two in the same drawing) feeders 20, and can simultaneously hold multiple (two) feeders 20. In addition, each of two holding sections 41 is independently movable along an attachment/detachment direction (Y direction in the embodiment) of feeder 20 by using, for example, the linear motion mechanism or the like, and can simultaneously move multiple (two) feeders 20 along the Y direction.

Further, two holding sections 41 are integrally movable in the vertical direction (Z direction) by using, for example, the linear motion mechanism or the like, and can simultaneously move multiple (four) feeders 20 in the Z direction. Also, conveyance device 40a may include, for example, multiple (four) holding sections 41. In this case, each of multiple (four) holding sections 41 can clamp one feeder 20, to independently move multiple (four) feeders 20 in the Y direction and the Z direction. In addition, the form of holding section 41 is not limited to the clamp mechanism and the linear motion mechanism, and can take various forms. For example, holding section 41 may include a protrusion portion that can be fitted into a hole portion provided in feeder 20. In this case, feeder 20 is held by fitting the protrusion portion of holding section 41 into the hole portion of feeder 20.

Control device 42 includes a well-known computing device and storage device, to constitute a control circuit. Control device 42 is connected to four component mounters 10, exchange system 30, storage device 50, and line management device 60 in a communicable manner. Control device 42 controls the traveling of conveyance device 40a, the operations of two holding sections 41, and the like. With the above-described configuration, conveyance device 40a can move to a predetermined position along first rail 31 and second rail 32, and can perform the exchange operation of feeder 20 at a stop position.

Storage device 50 can store not only feeder 20 but also device DD0 used in the production of product board 900 using board work machine WM0. For example, when board work machine WM0 is component mounter 10, device DD0 includes a tray unit that accommodates a tray on which multiple components 91 are arranged and a wafer component supply device that can supply wafer components. A holding member supply device (nozzle station when the holding member is the suction nozzle) capable of supplying the holding member (suction nozzle, chuck, or the like) is included in device DD0. When board work machine WM0 is a solder printer that prints solder on board 90, a solder container that accommodates solder is included in device DD0.

As described above, storage device 50 can preliminarily hold device DD0 that is scheduled to be used in the production of product board 900 or can temporarily hold device DD0 that is no longer necessary for the production of product board 900. Further, conveyance device 40a can supply not only feeder 20 but also device DD0 carried in storage device 50 to first slot 12a or second slot 12b, and can collect device DD0 that is no longer necessary for the production of product board 900 from first slot 12a or second slot 12b to storage device 50.

Further, board work machine WM0 may include not only component mounter 10 but also first slot 12a and second slot 12b, and device DD0 to be held is not limited to feeder 20. That is, board work machine WM0 includes first slot 12a that can hold device DD0 to be used in the production of product board 900, and second slot 12b that can preliminarily hold device DD0 that is scheduled to be used in the production of product board 900 or can temporarily hold device DD0 that is no longer necessary for the production of product board 900.

### 1-4. Configuration Example of Production Guidance Device 70

In the present description, for example, a thing supplied from device DD0 such as component 91 supplied from feeder 20 or the tray unit or solder supplied from the solder container is referred to as article MD0. When article MD0 supplied from device DD0 remaining in production line WL0 is insufficient, the production of product board 900 is stopped in board work machine WM0. Therefore, it is necessary to supply device DD0 to production line WL0. In addition, it is necessary to supply device DD0 to production line WL0 also in the changeover of board work machine WM0.

For example, in a production line that does not include first slot 12a, second slot 12b, storage device 50, and conveyance device 40a, device DD0 cannot be automatically exchanged. Therefore, the worker needs to prepare each of device DD0 necessary for the changeover work of board work machine WM0 and device DD0 necessary for the replenishment work with respect to board work machine WM0, and supply prepared devices DD0 to board work machine WM0.

Specifically, the changeover work of board work machine WM0 is performed for each predetermined production unit (corresponding to unit production described later) of product board 900. For example, when device DD0 is feeder 20, the worker sets predetermined reel 23 on feeder 20 in advance in an off-line set up area and moves reel 23 to cart 40b. Then, the worker moves cart 40b to an on-line set up area near the production line before the production unit is switched, and exchanges feeder 20 for each board work machine WM0. The worker also needs to collect feeder 20 that is no longer necessary for the production of product board 900 from board work machine WM0.

Replenishment work with respect to board work machine WM0 is performed separately from the changeover work. For example, the worker sets predetermined reel 23 on feeder 20 in a replenishment area near the production line. Each time component 91 runs out, the worker exchanges feeder 20 in board work machine WM0. As described above, in the above embodiment, the changeover work with respect to board work machine WM0 and the replenishment work with respect to board work machine WM0 are different types of work, and the worker is necessary for each area. Therefore, the work of the worker becomes complicated, and the work efficiency may decrease.

Therefore, board work machine WM0 of the embodiment includes first slot 12a and second slot 12b. Production line WL0 of the embodiment includes storage device 50 and conveyance device 40a. Further, production line WL0 is provided with production guidance device 70. Production guidance device 70 includes plan section 71 and guidance section 72. Plan section 71 and guidance section 72 can be provided in various control devices, management devices, and the like. For example, at least one of plan section 71 and guidance section 72 can be provided in line management device 60. At least one of plan section 71 and guidance section 72 may be provided in a management device that manages multiple production lines WL0. At least one of plan section 71 and guidance section 72 may be formed on a cloud.

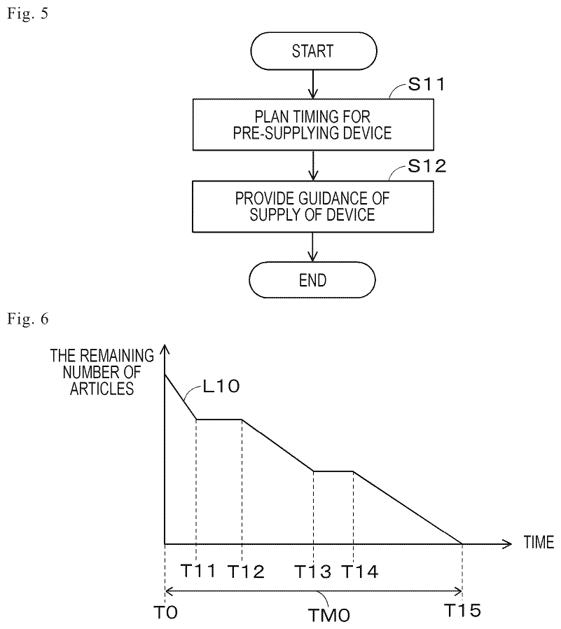

As illustrated in FIG. 4, plan section 71 and guidance section 72 of the embodiment are provided in line management device 60. Further, production guidance device 70 executes control in accordance with a flowchart illustrated in FIG. 5. Plan section 71 performs the processing illustrated in step S11. Guidance section 72 performs the processing illustrated in step S12.

### 1-4-1. Plan Section 71

As illustrated in FIGS. 1 and 2, board work machine WM0 of the embodiment includes first slot 12a and second slot 12b. Production line WL0 of the embodiment includes storage device 50 and conveyance device 40a. All of first slot 12a, second slot 12b, and storage device 50 can hold device DD0, and conveyance device 40a can move device DD0 between first slot 12a, second slot 12b, and storage device 50.

Therefore, in production line WL0, device DD0 necessary for the changeover work of board work machine WM0 and the replenishment work of device DD0 with respect to board work machine WM0 is pre-supplied from storage device 50 to an empty region of at least one of first slot 12a and second slot 12b by using conveyance device 40a. Accordingly, production line WL0 of the embodiment can execute the work by the same method without distinguishing the changeover work and the replenishment work of board work machine WM0.

Plan section 71 plans the timing for pre-supplying device DD0 (step S11 illustrated in FIG. 5). Plan section 71 can take various forms as long as the timing for pre-supplying device DD0 can be planned. For example, production line WL0 can produce product board 900 based on a production plan in which a type, a production quantity, and a production period of product boards 900 to be produced, and device DD0 to be used for the production of product board 900 are planned.

In this case, plan section 71 can plan the timing for pre-supplying device DD0 based on a remaining number of articles MD0 that can be supplied from device DD0 held in any of first slot 12a, second slot 12b, and storage device 50 and a scheduled number of articles MD0 to be used, which is expected when product board 900 is produced in accordance with the production plan.

Polygonal line L10 in FIG. 6 illustrates an example of a temporal change in the remaining number of predetermined articles MD0. A vertical axis in the same drawing indicates the remaining number of articles MD0 in first slot 12a, second slot 12b, and storage device 50, and a horizontal axis indicates a time. Time TO indicates a current time, and time T15 indicates a time when the remaining number of articles MD0 becomes zero. The time from time T0 to time T15 is a time during which board work machine WM0 can continue the production of product board 900 using articles MD0 remaining in first slot 12a, second slot 12b, and storage device 50, and is referred to as production continuable time TM0.

Plan section 71 plans the timing for pre-supplying device DD0 such that the pre-supply of device DD0 is completed by time T15 at which production continuable time TM0 becomes zero at the latest. Specifically, in the production plan, the type, the production quantity, and the production period of product board 900 to be produced, and device DD0 to be used for the production of product board 900 are planned, and thus plan section 71 can acquire the scheduled number of articles MD0 to be used by referring to the production plan. Therefore, plan section 71 can acquire the temporal change in the remaining number of articles MD0 indicated by polygonal line L10.

When production line WL0 produces product board 900 in accordance with the production plan, the scheduled number of articles MD0 to be used per unit time in production line WL0 varies depending on a difference in the type of product board 900 to be produced. For example, a slope of polygonal line L10 is different in the time from time T0 to time T11, the time from time T12 to time T13, and the time from time T14 to time T15. In addition, the remaining number of articles MD0 is constant and does not decrease in the time from time T11 to time T12 and the time from time T13 to time T14. This indicates that, depending on the type of product board 900 to be produced, device DD0 capable of supplying article MD0 of the type illustrated in the same drawing is not be used for the production in some cases.

For example, plan section 71 can make a plan for pre-supplying device DD0 at a timing at which the remaining number of articles MD0 in first slot 12a, second slot 12b, and storage device 50 becomes smaller than a predetermined number (for example, a predetermined timing of the time from time T14 to time T15). The predetermined number described above can be set freely. In addition, plan section 71 can also formulate a plan for pre-supplying device DD0 at any timing of a time during which device DD0 is not used for the production (for example, the time from time T13 to time T14).

In this way, plan section 71 can plan the timing for pre-supplying device DD0 necessary for the replenishment work of board work machine WM0. By referring to the production plan, plan section 71 can obtain the period when device DD0 is necessary for the changeover work of board work machine WM0. Plan section 71 can plan the timing for pre-supplying device DD0 necessary for the changeover work of board work machine WM0 before the period.

Device DD0 pre-supplied using conveyance device 40a is prepared by the worker. Specifically, as illustrated in FIG. 1, work area 80 is provided in production line WL0. Work area 80 includes workbench 81, shelf 82, and mobile terminal 83. In work area 80, the worker performs kitting work, arrangement preparation work, cleanup work, and the like on device DD0.

For example, when device DD0 is feeder 20, the worker sets predetermined reel 23 on feeder 20 and enables supply to production line WL0. Specifically, the worker sets predetermined reel 23 on feeder 20 on workbench 81 (kitting work) and installs reel 23 on shelf 82. The worker can acquire reel 23 and feeder 20 from storage 100. Reel 23 and feeder 20 can also be acquired by cart 40b, such as an automated guided vehicle or an autonomous mobile robot, from storage 100 that is an automatic warehouse. The worker moves feeder 20 installed on shelf 82 with reels 23 set to cart 40b (arrangement preparation work). Then, cart 40b conveys feeder 20 on which reel 23 is set to storage device 50 of production line WL0.

In the kitting work, the worker reads an identification code attached to reel 23 using, for example, reading device 84 of mobile terminal 83 or the like. In addition, the worker reads an identification code attached to feeder 20 using reading device 84 of mobile terminal 83 or the like. Accordingly, identification information for identifying reel 23 and identification information for identifying feeder 20 are transmitted to an article management device that manages article MD0. When the identification information is acquired, the article management device stores the identification information of reel 23 and the identification information of feeder 20 in a storage device in association with each other. The article management device can also update location information of feeder 20 when feeder 20 moves, for example.

For example, when moving feeder 20 to shelf 82, the worker reads the identification code of feeder 20 using reading device 84 of mobile terminal 83 or the like. When mobile terminal 83 has a positioning function, mobile terminal 83 reads the identification code and transmits the location information of feeder 20 to the article management device. The article management device updates the location information of reel 23 and feeder 20 stored in the storage device to the received location information. The worker can also read a location code provided in work area 80 using reading device 84 of mobile terminal 83 or the like. Accordingly, positional information of the area in which the location code is provided is transmitted to the article management device, and the article management device similarly updates the location information. In addition, when feeder 20 is set in the slot of shelf 82 and power is supplied, the article management device can communicate with feeder 20 and update the location information of feeder 20.

Cart 40b conveys, for example, feeder 20 that is no longer necessary for the production of product board 900 from storage device 50 of production line WL0 to work area 80. In work area 80, the worker cleans up feeder 20 that is no longer necessary for the production of product board 900, as necessary (cleanup work). Specifically, the worker takes out reel 23 from feeder 20. Taken-out reel 23 is, for example, conveyed to storage 100 by cart 40b and stored in storage 100. In this case, a correspondence relationship between the identification information of reel 23 and the identification information of feeder 20 that are stored in the storage device is deleted. When the cleanup work is unnecessary, reel 23 and feeder 20 are stored in a set state on, for example, shelf 82. In this case, a correspondence relationship between the identification information of reel 23 and the identification information of feeder 20 that are stored in the storage device is maintained.

### 1-4-2. Guidance Section 72

Guidance section 72 guides the worker to supply device DD0 to storage device 50 in a predetermined period before the timing for pre-supply planned by plan section 71 (step S12 illustrated in FIG. 5). Guidance section 72 can take various forms as long as guidance section 72 can guide the worker to supply device DD0 to storage device 50.

For example, guidance section 72 can display a list of devices DD0 to be prepared by the worker and provide the guidance of the supply of devices DD0. Guidance section 72 can also provide a guidance of information related to devices DD0 in the order of devices DD0 prepared by the worker. Further, guidance section 72 can also provide a guidance of a remaining time until the timing for pre-supplying device DD0. Guidance section 72 can also provide a guidance of the supply of device DD0 in mobile terminal 83 carried by the worker.

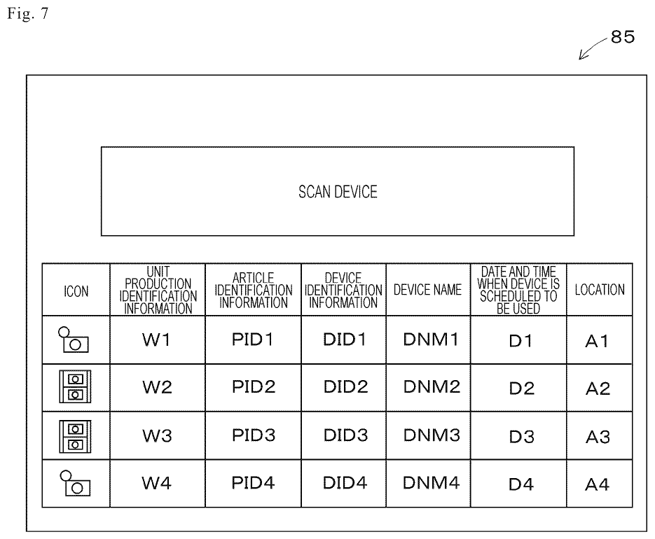

Specifically, guidance section 72 can display the list of devices DD0 illustrated in FIG. 7 on display device 85 of mobile terminal 83 illustrated in FIG. 1 to provide the guidance of the supply of devices DD0. FIG. 7 illustrates an example of a display screen displayed on display device 85 of mobile terminal 83, in which an icon, unit production identification information, article identification information, device identification information, a device name, a date and time when the device is scheduled to be used, and a location are listed.

The icon schematically illustrates the work of device DD0 performed by the worker. For example, the uppermost icon and the lowermost icon in FIG. 7 indicate that the worker needs to perform the kitting work and the arrangement preparation work described above. A second icon and a third icon in the same drawing indicate that the kitting work has already been completed and the worker needs to perform the arrangement preparation work described above.

The unit production identification information is information capable of identifying the unit production. In the production plan, the order of multiple unit productions is defined. For example, when the type of product board 900 to be produced is switched, new unit production is set in the production plan. When the production lot is switched even when the type of product board 900 to be produced is the same, new unit production is set in the production plan. The same drawing illustrates that the unit production indicated by unit production identification information WI to unit production identification information W4 is performed in this order.

The article identification information is information capable of identifying article MD0 supplied from device DD0. The same drawing shows that articles MD0 indicated by article identification information PIDI to article identification information PID4 are necessary in this order. The device identification information is information capable of identifying device DD0. The same drawing illustrates that the worker has to prepare devices DD0 indicated by device identification information DID1 to device identification information DID4 in this order.

The device name refers to the name of device DD0. The same drawing illustrates that the names of devices DD0 indicated by device identification information DID1 to device identification information DID4 are represented by device name DNMI to device name DNM4 in this order. The date and time when the device is scheduled to be used refers to a scheduled date and time when device DD0 is used in production line WL0. Devices DD0 indicated by device identification information DID1 to device identification information DID4 are used at date and time DI to date and time D4 in this order. Date and time DI to date and time D4 are represented by month, date, time, and minute. The location refers to the location of device DD0. Devices DD0 indicated by device identification information DID1 to device identification information DID4 are present at locations A1 to A4 in this order.

In addition, guidance section 72 can also provide the guidance of the remaining time until the timing for pre-supplying device DD0. For device DD0 to be prepared first by the worker (in FIG. 7, device DD0 indicated by device identification information DID1), guidance section 72 can display the remaining time until the timing for pre-supplying device DD0. When the preparation work of device DD0 indicated by device identification information DID1 is completed by the worker, guidance section 72 can display the remaining time until the timing for pre-supplying device DD0 for device DD0 to be prepared next by the worker (in the same drawing, device DD0 indicated by device identification information DID2).

Then, guidance section 72 stops displaying the information related to device DD0 indicated by device identification information DID1 for which the preparation work has been completed, and moves up and displays the information related to devices DD0 indicated by device identification information DID2 to device identification information DID4. Further, guidance section 72 can display information related to device DD0 to be prepared by the worker next to device DD0 indicated by device identification information DID4 in the lowermost stage. In this way, guidance section 72 can also provide the guidance of the information related to devices DD0 in the order of devices DD0 prepared by the worker. Accordingly, the worker can recognize the information related to device DD0 to be prepared in a necessary order.

Further, guidance section 72 provides the guidance of the supply of device DD0 in a predetermined period before the timing at which device DD0 is pre-supplied. Specifically, guidance section 72 can guide the worker to supply device DD0 based on a required time including a work time required for the worker to perform the preparation work of device DD0 and a conveyance time until device DD0 is conveyed to storage device 50 by cart 40b. For example, guidance section 72 starts the guidance of the supply of device DD0 before the timing at which device DD0 is pre-supplied by a time obtained by adding a predetermined margin time to the required time.

As the time during which the worker does not perform the preparation work of device DD0 after the guidance of the supply of device DD0 is provided becomes longer, the margin time becomes shorter, and the worker needs to hurry the preparation work of device DD0. Therefore, guidance section 72 can provide the guidance of the supply of device DD0 again when the margin time becomes shorter than a predetermined allowable time. In addition, guidance section 72 can also provide the guidance of the supply of device DD0 again when the margin time is over. Further, guidance section 72 can also provide the guidance of the supply of device DD0 each time a predetermined time elapses after the margin time is over.

The work time can be set to a work standard time required when a standard worker performs the preparation work of device DD0. The work time can also be set in accordance with the work capacity of the worker. For example, the work time can be set to a time longer than the work standard time as the work capacity of the worker is lower. Further, the work time can be set for each production line WL0, or can be set for each production facility including multiple production lines WL0. Guidance section 72 can also provide voice guidance of the supply of device DD0 to storage device 50. Further, guidance section 72 can also provide the guidance of the supply of device DD0 to storage device 50 by vibrating mobile terminal 83. As described above, guidance section 72 can provide the guidance of the supply of device DD0 to storage device 50 through at least one of the visual sense, the auditory sense, and the tactile sense of the worker.

Guidance section 72 can change the guidance of the preparation work of device DD0 in accordance with the progress status of the preparation work of device DD0 performed by the worker. For example, an indication to scan the device is displayed on the display screen illustrated in FIG. 7. That is, when the worker performs the kitting work, guidance section 72 guides the worker to perform the preparation work of device DD0 so as to read the identification code attached to device DD0 using reading device 84 of mobile terminal 83 or the like.

When the identification code attached to device DD0 is read by the worker, guidance section 72 provides the guidance of the next preparation work for device DD0 on the display screen illustrated in FIG. 7. For example, when device DD0 is feeder 20, when the identification code attached to feeder 20 is read, guidance section 72 guides the worker to read the identification code attached to reel 23 using reading device 84 of mobile terminal 83 or the like. Guidance section 72 guides the worker to set reel 23 on feeder 20 and install feeder 20 at a predetermined position of shelf 82.

In addition, when the worker performs the arrangement preparation work, guidance section 72 performs guidance such that feeder 20 in which reel 23 is set and which is installed at a predetermined position of shelf 82 is moved to a predetermined slot of cart 40b. As described above, guidance section 72 can change the guidance of the preparation work of device DD0 in accordance with a progress status of the preparation work of device DD0 performed by the worker. Accordingly, the worker can easily recognize the preparation work of device DD0 to be performed next.

In production line WL0 of the embodiment, conveyance device 40a can move device DD0 among first slot 12a, second slot 12b, and storage device 50. Therefore, device DD0 need only to be supplied to storage device 50, and the worker does not need to distinguish whether device DD0 to be supplied to storage device 50 is used for the changeover work or the replenishment work. Therefore, guidance section 72 can provide the guidance of the supply of device DD0 without distinguishing whether device DD0 to be supplied to storage device 50 is used for the changeover work or the replenishment work.

Further, for example, when conveyance device 40a moves device DD0 between storage device 50 and first slot 12a or second slot 12b, it is difficult for storage device 50 to receive the carry-in of device DD0 by cart 40b. Therefore, when storage device 50 can receive the carry-in of device DD0, guidance section 72 can provide the guidance of the arrangement of device DD0.

Specifically, guidance section 72 acquires an operation status of conveyance device 40a from line management device 60. Then, guidance section 72 can provide the guidance of the arrangement of device DD0 such that device DD0 is arranged in a time zone in which conveyance device 40a does not perform work on storage device 50. For example, in a case where device DD0 is feeder 20, when the guidance of the arrangement of feeder 20 is provided, the worker performs the arrangement preparation work described above. Specifically, the worker moves feeder 20 installed on shelf 82 with reels 23 set to cart 40b. Then, cart 40b conveys feeder 20 on which reel 23 is set to storage device 50 of production line WL0. Guidance section 72 provides the guidance of the arrangement of feeder 20 by calculating back from a scheduled time when feeder 20 is supplied to storage device 50.

Further, as the number of carts 40b used for conveying device DD0 increases, the control of carts 40b becomes complicated, and it becomes difficult for the worker to recognize carts 40b on which device DD0 is to be installed. Therefore, guidance section 72 can guide the worker to arrange device DD0 to storage device 50 using the minimum number of carts 40b. For example, guidance section 72 can guide the worker to arrange device DD0 to storage device 50 using one cart 40b. When it is difficult to arrange device DD0 using one cart 40b, guidance section 72 can sequentially increase the number of carts 40b to be used.

Guidance section 72 can also provide the worker with the guidance such that the number of devices DD0 installed on cart 40b approaches the maximum number of devices DD0 that can be installed on cart 40b. In some cases, the worker does not know the number of devices DD0 to be installed on one cart 40b. In this case, guidance section 72 can also provide the worker with the guidance of the number of devices DD0 to be installed at one time on cart 40b to which device DD0 is arranged.

In addition, device DD0 that is no longer necessary for the production of product board 900 is collected in storage device 50. When cart 40b only supplies device DD0 and does not collect device DD0, it is necessary to separately move cart 40b to storage device 50 for collecting device DD0, and the conveyance efficiency of cart 40b decreases. Therefore, guidance section 72 can guide the worker to collect device DD0 that is no longer necessary for the production of product board 900 collected in storage device 50 when device DD0 is supplied to storage device 50. This improves the conveyance efficiency of cart 40b.

In production line WL0 of the embodiment, device DD0 need only to be supplied to storage device 50, and the worker does not need to distinguish whether device DD0 supplied to storage device 50 is used for the changeover work or the replenishment work. Therefore, the worker can perform the preparation work of device DD0 related to the changeover work and the replenishment work in the same method, and work errors can be reduced by unifying the work method. It is also possible to reduce the cost of work education for the worker. Furthermore, the number of workers can be reduced by arranging device DD0 to storage device 50 using the minimum number of carts 40b. For example, in same work area 80, the worker can consistently perform the kitting work, the arrangement preparation work, and the cleanup work of device DD0 by himself/herself.

### 1-4-3. Others

In the present description, feeder 20 is described as an example of device DD0. However, device DD0 is not limited to feeder 20. As described above, device DD0 may be, for example, the tray unit, the solder container, or the like.

Further, conveyance device 40a of the embodiment is provided to be able to travel on traveling path 30R extending in the conveyance direction (X direction) of board 90. Similarly to cart 40b, conveyance device 40a may be an automated guided vehicle, an autonomous mobile robot, or the like. In this case, production line WL0 can include cart 40b instead of exchange system 30 and conveyance device 40a. The matters described in the present description can be selected as appropriate and applied. Further, the matters described in the present description can be combined as appropriate.

### 2. Production Guidance Method

The above description regarding production guidance device 70 can be similarly applied to the production guidance method. Specifically, the production guidance method includes a plan step and a guidance step. The plan step corresponds to the control performed by plan section 71. The guidance step corresponds to the control performed by guidance section 72. The production guidance method is executed by the management device through the processing of the management device.

### 3. Example of Effects of Embodiment

In production line WL0, device DD0 necessary for the changeover work of board work machine WM0 and the replenishment work of device DD0 to board work machine WM0 can be pre-supplied. Further, with production guidance device 70, it is possible to provide the worker with the guidance of the supply of device DD0 in a predetermined period before the timing for pre-supplying device DD0. Therefore, the worker can collectively perform the preparation work of device DD0 without distinguishing the changeover work and the replenishment work of board work machine WM0, and the work efficiency of the worker is improved. The above description regarding production guidance device 70 can be similarly applied to the production guidance method.

### REFERENCE SIGNS LIST

12a: first slot, 12b: second slot, 40a: conveyance device,
40b: cart, 50: storage device, 70: production guidance device, 71: plan section, 72: guidance section, 83: mobile terminal, 90: board,
900: product board, DD0: device, MD0: article, WL0: production line,
WM0: board work machine.

1. A production guidance device to be applied to a production line including
a board work machine including a first slot capable of holding a device to be used for production of a product board and a second slot capable of preliminarily holding the device that is scheduled to be used in the production of the product board or capable of temporarily holding the device that is no longer necessary for the production of the product board, the board work machine being configured to perform predetermined board work on a board to produce the product board,
a storage device capable of preliminarily holding the device that is scheduled to be used in the production of the product board or capable of temporarily holding the device that is no longer necessary for the production of the product board, and
a conveyance device configured to supply the device supplied to the storage device to the first slot or the second slot and collect the device that is no longer necessary for the production of the product board from the first slot or the second slot to the storage device,
the production guidance device comprising:
a plan section configured to plan a timing for pre-supplying the device, which is necessary for changeover work of the board work machine and replenishment work of the device with respect to the board work machine, from the storage device to an empty region of at least one of the first slot and the second slot by using the conveyance device; and
a guidance section configured to provide a worker with a guidance of supply of the device to the storage device during a predetermined period before the timing for pre-supplying planned by the plan section.

2. The production guidance device according to claim 1,
wherein the production line produces the product board based on a production plan in which a type, a production quantity, and a production period of the product board to be produced, and the device to be used for the production of the product board are planned, and
the plan section plans the timing for pre-supplying the device based on a remaining number of articles suppliable from the device held in any of the first slot, the second slot, and the storage device, and a scheduled number of the articles to be used, which is expected when the product board is produced in accordance with the production plan.

3. The production guidance device according to claim 1, wherein the guidance section provides the guidance of the supply of the device without distinguishing whether the device to be supplied to the storage device is used for the changeover work or the replenishment work.

4. The production guidance device according to claim 1, wherein the guidance section provides the guidance of the supply of the device in a mobile terminal carried by the worker.

5. The production guidance device according to claim 1, wherein the guidance section displays a list of the devices to be prepared by the worker and provides the guidance of the supply of the devices.

6. The production guidance device according to claim 1, wherein the guidance section provides a guidance of arrangement of the device when the storage device is capable of receiving carrying-in of the device.

7. The production guidance device according to claim 1, wherein the guidance section guides the worker to arrange the device to the storage device using a minimum number of carts.

8. The production guidance device according to claim 1, wherein the guidance section provides the worker with a guidance of the number of the devices to be installed at one time on a cart to which the device is arranged.

9. The production guidance device according to claim 1, wherein the guidance section guides the worker to collect, when the device is supplied to the storage device, the device that is no longer necessary for the production of the product board collected in the storage device.

10. A production guidance method to be applied to a production line including
a board work machine including a first slot capable of holding a device to be used for production of a product board and a second slot capable of preliminarily holding the device that is scheduled to be used in the production of the product board or capable of temporarily holding the device that is no longer necessary for the production of the product board, the board work machine being configured to perform predetermined board work on a board to produce the product board,
a storage device capable of preliminarily holding the device that is scheduled to be used in the production of the product board or capable of temporarily holding the device that is no longer necessary for the production of the product board, and
a conveyance device configured to supply the device supplied to the storage device to the first slot or the second slot and collect the device that is no longer necessary for the production of the product board from the first slot or the second slot to the storage device,
the production guidance method comprising:
a plan step of planning a timing for pre-supplying the device, which is necessary for changeover work of the board work machine and replenishment work of the device with respect to the board work machine, from the storage device to an empty region of at least one of the first slot and the second slot by using the conveyance device; and
a guidance step of providing a worker with a guidance of supply of the device to the storage device during a predetermined period before the timing for pre-supplying planned by the plan step.
